(19) United States
(12) Patent Application Publication
(10) Pub. No.: US 2024/0206284 A1
(43) Pub. Date: Jun. 20, 2024

(54) DISPLAY DEVICE AND MANUFACTURING METHOD THEREOF

(71) Applicant: Japan Display Inc., Tokyo (JP)

(72) Inventors: Nobuo IMAI, Tokyo (JP); Hiroshi OGAWA, Tokyo (JP); Yuya YAMAMOTO, Tokyo (JP)

(73) Assignee: Japan Display Inc., Tokyo (JP)

(21) Appl. No.: 18/522,293

(22) Filed: Nov. 29, 2023

(30) Foreign Application Priority Data
Dec. 15, 2022 (JP) 2022-200380

(51) Int. Cl. H10K 59/80; H10K 71/16; H10K 71/60

(52) U.S. Cl. CPC H10K 59/8722; H10K 59/80521; H10K 71/16; H10K 71/60; H10K 2102/351

(57) ABSTRACT

According to one embodiment, a display device includes a lower electrode, a rib, a partition including bottom, stem and top portions, an organic layer covering the lower electrode, an upper electrode covering the organic layer and contacting the bottom portion, and a sealing layer continuously covering the partition and a thin film including the organic layer and the upper electrode. The bottom portion is formed of a molybdenum-tungsten alloy. A height from a lower surface of the bottom portion to an upper surface of the stem portion is less than or equal to 500 nm. A thickness of the sealing layer is less than or equal to 1.5 μm. A thickness of the bottom portion is greater than or equal to 50 nm.

### CROSS-REFERENCE TO RELATED APPLICATIONS

This application is based upon and claims the benefit of priority from Japanese Patent Application No. 2022-200380, filed Dec. 15, 2022, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When such a display device is manufactured, a technique which improves the yield is required.

### BRIEF DESCRIPTION OF THE DRAWINGS

FIG. 1 is a diagram showing a configuration example of a display device according to an embodiment.

FIG. 2 is a schematic plan view showing an example of the layout of subpixels.

FIG. 3 is a schematic cross-sectional view of the display device along the III-III line of FIG. 2.

FIG. 4 is a schematic cross-sectional view showing an example of a configuration which could be applied to a partition.

FIG. 5 is a flowchart showing an example of the manufacturing method of the display device.

FIG. 6 is a schematic cross-sectional view showing an example of a process for forming a rib and the partition.

FIG. 7 is a schematic cross-sectional view showing a process following FIG. 6.

FIG. 8 is a schematic cross-sectional view showing a process following FIG. 7.

FIG. 9 is a schematic cross-sectional view showing a process following FIG. 8.

FIG. 10 is a schematic cross-sectional view showing a process following FIG. 9.

FIG. 11 is a schematic cross-sectional view showing a process following FIG. 10.

FIG. 12 is a schematic cross-sectional view showing an example of a process for forming display elements.

FIG. 13 is a schematic cross-sectional view showing a process following FIG. 12.

FIG. 14 is a schematic cross-sectional view showing a process following FIG. 13.

FIG. 15 is a schematic cross-sectional view showing a process following FIG. 14.

FIG. 16 is a schematic cross-sectional view showing a process following FIG. 15.

FIG. 17 is a schematic cross-sectional view showing a process following FIG. 16.

### DETAILED DESCRIPTION

In general, according to one embodiment, a display device comprises a lower electrode, a rib comprising a pixel aperture which overlaps the lower electrode, a partition which includes a conductive bottom portion provided on the rib, a stem portion provided on the bottom portion, and a top portion provided on the stem portion and protruding from a side surface of the stem portion, an organic layer which covers the lower electrode through the pixel aperture and emits light based on application of voltage, an upper electrode which covers the organic layer and is in contact with the bottom portion, and a sealing layer which continuously covers the partition and a thin film including the organic layer and the upper electrode. The bottom portion is formed of a molybdenum-tungsten alloy. A height from a lower surface of the bottom portion to an upper surface of the stem portion is less than or equal to 500 nm. A thickness of the sealing layer is less than or equal to 1.5 μm. A thickness of the bottom portion is greater than or equal to 50 nm.

According to another embodiment, a manufacturing method of a display device includes forming a lower electrode, forming a rib which covers at least part of the lower electrode, forming a partition on the rib, the partition including a conductive bottom portion, a stem portion located on the bottom portion and a top portion located on the stem portion, forming an organic layer which covers the lower electrode and emits light based on application of voltage, forming an upper electrode which covers the organic layer and is in contact with the bottom portion, and forming a sealing layer which continuously covers the partition and a thin film including the organic layer and the upper electrode and has a thickness less than or equal to 1.5 μm. The forming the partition includes forming a first layer having a thickness greater than or equal to 50 nm using a molybdenum-tungsten alloy, forming a second layer on the first layer, the second layer comprising an upper surface in which a height from a lower surface of the first layer is less than or equal to 500 nm, forming a third layer on the second layer, forming a resist on the third layer, forming the top portion by removing a portion of the third layer exposed from the resist, forming the stem portion by removing a portion of the second layer exposed from the top portion and by decreasing a width of the second layer which remains under the top portion so as to be less than a width of the top portion, and forming the bottom portion by removing a portion of the first layer exposed from the stem portion.

These configurations can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction z, the appearance is defined as a plan view.

The display device of the present embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

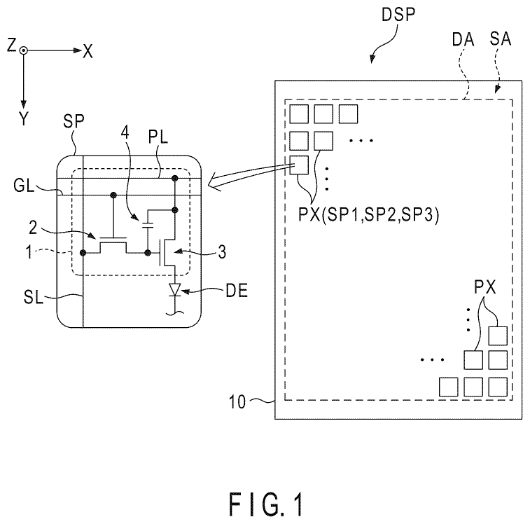

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. It should be noted that each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

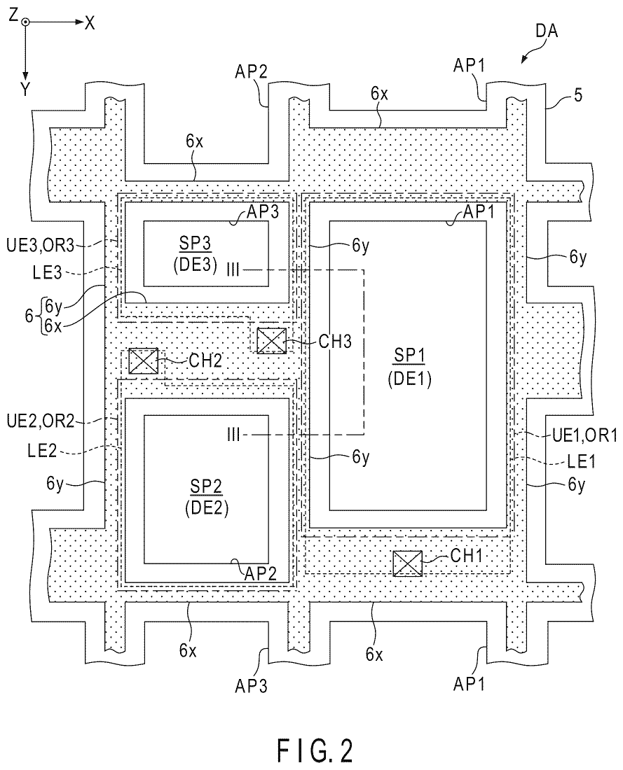

FIG. 2 is a schematic plan view showing an example of the layout of subpixels SP1, SP2 and SP3. In the example of FIG. 2, each of subpixels SP2 and SP3 is adjacent to subpixel SP1 in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X. It should be noted that the layout of subpixels SP1, SP2 and SP3 is not limited to the example of FIG. 2.

A rib 5 and a partition 6 are provided in the display area DA. The rib 5 comprises pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between two pixel apertures AP1 which are adjacent to each other in the second direction Y and between the pixel apertures AP2 and AP3 which are adjacent to each other in the second diction Y. Each second partition 6y is provided between the pixel apertures AP1 and AP2 which are adjacent to each other in the first direction X and between the pixel apertures AP1 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 and the partition 6 surround each of these display elements DE1, DE2 and DE3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3. In the example of FIG. 2, the contact holes CH1, CH2 and CH3 overlap the rib 5 and the partition 6 as a whole. However, the configuration is not limited to this example.

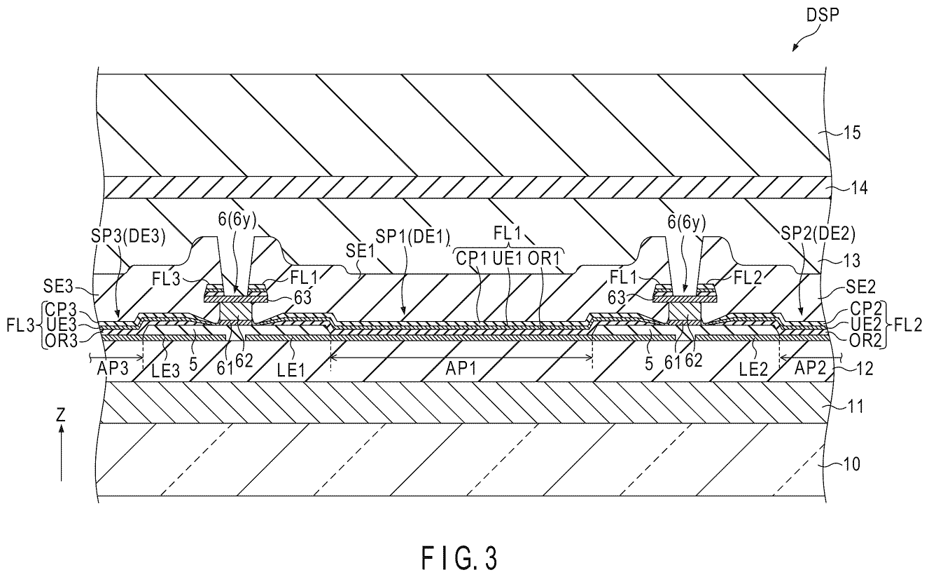

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an insulating layer 12. The insulating layer 12 functions as a planarization film which planarizes the irregularities formed by the circuit layer 11. Although not shown in the section of FIG. 3, the contact holes CH1, CH2 and CH3 described above are provided in the insulating layer 12.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5.

The partition 6 comprises a bottom portion 61 provided on the rib 5, a stem portion 62 provided on the bottom portion 61 and a top portion 63 provided on the stem portion 62. The top portion 63 has a width greater than that of the stem portion 62. By this configuration, in FIG. 3, the both end portions of the top portion 63 protrude relative to the side surfaces of the stem portion 62. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3.

The thin film FL1 is partly located on the top portion 63. This portion is spaced apart from, of the thin film FL1, the portion located under the partition 6 (in other words, the portion which constitutes the display element DE1). Similarly, the thin film FL2 is partly located on the top portion 63. This portion is spaced apart from, of the thin film FL2, the portion located under the partition 6 (in other words, the portion which constitutes the display element DE2). Further, the thin film FL3 is partly located on the top portion 63. This portion is spaced apart from, of the thin film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the thin film FL1 and the partition 6 around subpixel SP1. The sealing layer SE2 continuously covers the thin film FL2 and the partition 6 around subpixel SP2. The sealing layer SE3 continuously covers the thin film FL3 and the partition 6 around subpixel SP3.

In the example of FIG. 3, the thin film FL1 and sealing layer SE1 located on the partition 6 between subpixels SP1 and SP2 are spaced apart from the thin film FL2 and sealing layer SE2 located on this partition 6. The thin film FL1 and sealing layer SE1 located on the partition 6 between subpixels SP1 and SP3 are spaced apart from the thin film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The insulating layer 12 is formed of an organic insulating material. Each of the rib 5 and the sealing layers 14, SE1, SE2 and SE3 can be formed of an inorganic insulating material such as silicon nitride (SiN), silicon oxide (SiO), silicon oxynitride (SiON) or aluminum oxide (Al₂O₃). Each of the rib 5 and the sealing layers 14, SE1, SE2 and SE3 may comprise a single-layer structure formed of one of the inorganic insulating materials, or may comprise a stacked structure in which the layers of two or more types of inorganic insulating materials are stacked. The inorganic insulating materials of the rib 5 and the sealing layers 14, SE1, SE2 and SE3 may be the same as each other or different from each other. For example, the rib 5 is formed of silicon oxynitride, and each of the sealing layers 14, SE1, SE2 and SE3 is formed of silicon nitride.

Each of the resin layers 13 and 15 is formed of, for example, a resinous material (organic insulating material) such as epoxy resin or acrylic resin. Each of the lower electrodes LE1, LE2 and LE3 comprises a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that at least one of the cap layers CP1, CP2 and CP3 may be omitted.

In the embodiment, the bottom portion 61 is formed of a molybdenum-tungsten alloy (MoW). The stem portion 62 can be formed of, for example, aluminum (Al). The stem portion 62 may be formed of an aluminum alloy. For the aluminum alloy, for example, an aluminum-neodymium alloy (AlNd), an aluminum-yttrium alloy (AlY) or an aluminum-silicon alloy (AlSi) could be used. The stem portion 62 may comprise a single-layer structure formed of aluminum or an aluminum alloy or may comprise a stacked structure including a plurality of layers formed of different materials. The stem portion 62 may include a layer formed of an insulating material such as silicon nitride, silicon oxide or silicon oxynitride.

The top portion 63 can be formed of, for example, a conductive material such as titanium, titanium nitride, molybdenum, tungsten, a molybdenum-tungsten alloy, a molybdenum-niobium alloy, ITO or IZO. The top portion 63 may comprise a single-layer structure formed of one of these materials or may comprise a stacked structure including a plurality of layers formed of different materials. The top portion 63 may include a layer formed of an insulating material such as silicon nitride, silicon oxide or silicon oxynitride.

The upper electrodes UE1, UE2 and UE3 are in contact with the bottom portions 61. Common voltage is applied to the bottom portions 61. This common voltage is applied to each of the upper electrodes UE1, UE2 and UE3. Pixel voltage is applied to the lower electrodes LE1, LE2 and LE3 through the pixel circuits 1 provided in subpixels SP1, SP2 and SP3, respectively.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

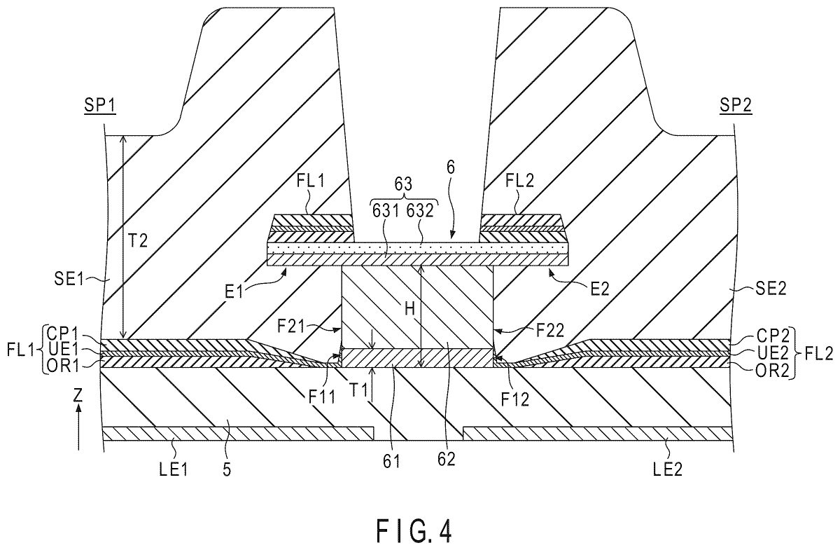

FIG. 4 is a schematic cross-sectional view showing an example of a configuration which could be applied to the partition 6. Here, this specification shows the portion located between subpixels SP1 and SP2 in the partition 6 as an example. A structure similar to that of FIG. 4 could be also applied to, in the partition 6, the portion located between subpixels SP1 and SP3 and the portion located between subpixels SP2 and SP3.

In the example of FIG. 4, each of the bottom portion 61 and the stem portion 62 comprises a single-layer structure. The top portion 63 comprises a first top layer 631, and a second top layer 632 provided on the first top layer 631. The materials of the first top layer 631 and the second top layer 632 could be appropriately selected from the materials of the top portion 63 described above. The bottom portion 61 and the top portion 63 are formed so as to be thinner than the stem portion 62.

The bottom portion 61 comprises a side surface F11 on the subpixel SP1 side and a side surface F12 on the subpixel SP2 side. The stem portion 62 comprises a side surface F21 on the subpixel SP1 side and a side surface F22 on the subpixel SP2 side.

In the example of FIG. 4, the side surfaces F11 and F21 are aligned with each other and form a plane which does not have a step. Similarly, the side surfaces F12 and F22 are aligned with each other and form a plane which does not have a step. From another viewpoint, in the example of FIG. 4, the width of the bottom portion 61 is equal to that of the stem portion 62.

As another example, the side surface F11 may be retracted or protrude slightly relative to the side surface F21. Similarly, the side surface F12 may be retracted or protrude slightly relative to the side surface F22. In FIG. 4, the side surfaces F11, F12, F21 and F22 are parallel to a third direction Z. However, the configuration is not limited to this example. For example, the side surfaces F11, F12, F21 and F22 may incline such that the widths of the bottom portion 61 and the stem portion 62 decrease toward the top portion 63.

The top portion 63 protrudes from the side surfaces F21 and F22. Specifically, the top portion 63 comprises an end portion E1 which protrudes from the side surface F21 and an end portion E2 which protrudes from the side surface F22.

The organic layer OR1 is spaced apart from the side surfaces F11 and F21. The upper electrode UE1 is in contact with at least part of the side surface F11. In the example of FIG. 4, the upper electrode UE1 covers the entire side surface F11 and is in contact with part of the side surface F21 as well. It should be noted that the configuration is not limited to this example. The upper electrode UE1 may not be in contact with the side surface F21.

Similarly, the organic layer OR2 is spaced apart from the side surfaces F12 and F22. The upper electrode UE2 is in contact with at least part of the side surface F12. In the example of FIG. 4, the upper electrode UE2 covers the entire side surface F12 and is in contact with part of the side surface F22 as well. It should be noted that the configuration is not limited to this example. The upper electrode UE2 may not be in contact with the side surface F22.

The sealing layer SE1 covers the thin film FL1 and also covers, of the side surface F21, the portion which is not covered with the upper electrode UE1, and the lower surface of the end portion E1. Similarly, the sealing layer SE2 covers the thin film FL2 and also covers, of the side surface F22, the portion which is not covered with the upper electrode UE2, and the lower surface of the end portion E2.

Here, the thickness of the bottom portion 61 is defined as T1. The thicknesses of the sealing layers SE1 and SE2 are defined as T2. The height from the lower surface of the bottom portion 61 to the upper surface of the stem portion 62 is defined as H. Thickness T2 is, for example, the average value of the thicknesses of several positions of the sealing layers SE1 and SE2. The sealing layer SE3 shown in FIG. 3 also has thickness T2. It should be noted that the thicknesses of the sealing layers SE1, SE2 and SE3 may be different from each other. Height H corresponds to the total thickness of the bottom portion 61 and the stem portion 62 or the distance from the upper surface of the rib 5 to the lower surface of the top portion 63.

Thickness T2 is greater than height H (T2>H). For example, thickness T2 is greater than or equal to twice height H2. In the embodiment, height H is less than or equal to 500 nm, and thickness T1 is greater than or equal to 50 nm and less than or equal to 100 nm. Thickness T2 is less than or equal to 1.5 μm and should be desirably less than or equal to 1.0 μm. Effects which are obtained by these numerical ranges are described later.

It should be noted that the configuration of the partition 6 shown in FIG. 4 is merely an example. Each of the bottom portion 61 and the stem portion 62 may comprise a stacked structure consisting of two or more layers. The top portion 63 may comprise a single-layer structure or may comprise a stacked structure consisting of three or more layers.

Now, this specification explains the manufacturing method of the display device DSP with reference to an example in which the partition 6 comprises the configuration shown in FIG. 4. Here, for example, this specification assumes a case where the rib 5 is formed of silicon oxynitride, and each of the sealing layers SE1, SE2 and SE3 is formed of silicon nitride, and the stem portion 62 is formed of aluminum, and the first top layer 631 is formed of titanium, and the second top layer 632 is formed of ITO. As described above, the bottom portion 61 is formed of a molybdenum-tungsten alloy.

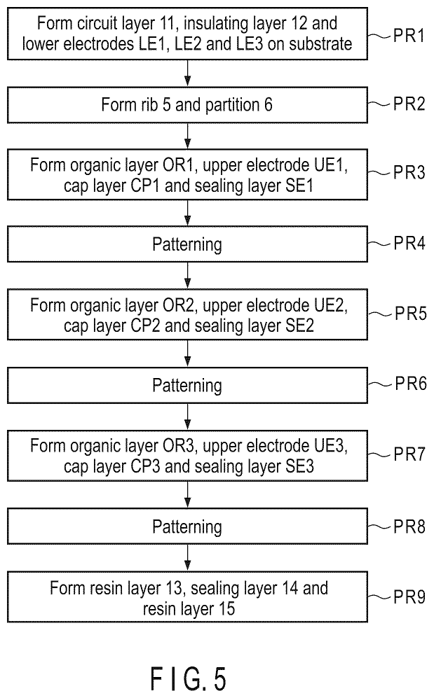

FIG. 5 is a flowchart showing an example of the manufacturing method of the display device DSP. To manufacture the display device DSP, first, the circuit layer 11, the insulating layer 12 and the lower electrodes LE1, LE2 and LE3 are formed on the substrate 10 (process PR1). Further, the rib 5 and the partition 6 are formed (process PR2).

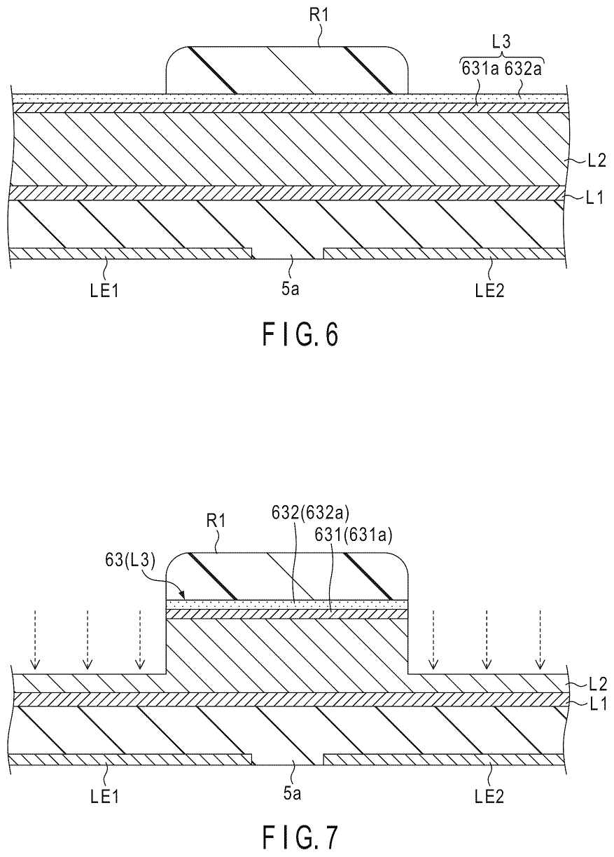

FIG. 6 to FIG. 11 are schematic cross-sectional views showing an example of process PR2 for forming the rib 5 and the partition 6. In these figures, the substrate 10, the circuit layer 11 and the insulating layer 12 are omitted.

In process PR2, as shown in FIG. 6, an insulating layer 5a which is processed so as to be the rib 5 is formed. A first layer L1 which is processed so as to be the bottom portion 61 is formed on the insulating layer 5a. A second layer L2 which is processed so as to be the stem portion 62 is formed on the first layer L1. A third layer L3 which is processed so as to be the top portion 63 is formed on the second layer L2. Further, a resist R1 patterned into the planar shape of the partition 6 is formed on the third layer L3. The third layer L3 includes a first top layer 631a, and a second top layer 632a which covers the first top layer 631a.

In the embodiment, the insulating layer 5a is formed of silicon oxynitride. The first layer L1 is formed of a molybdenum-tungsten alloy. The second layer L2 is formed of aluminum. The first top layer 631a is formed of titanium. The second top layer 632a is formed of ITO. The first layer L1 formed of a molybdenum-tungsten alloy is formed by, for example, sputtering which is performed on the film formation condition of a low temperature which is less than or equal to 100° C. Thus, when this sputtering is performed, the temperature of the inside of the chamber in which the target substrate for the formation of the first layer L1 is provided is set so as to be less than or equal to 100° C.

The thickness of the first layer L1 is greater than or equal to 50 nm and less than or equal to 100 nm. The total thickness of the first layer L1 and the second layer L2 is less than or equal to 500 nm. Thus, the second layer L2 comprises an upper surface such that the height from the lower surface of the first layer L1 is less than or equal to 500 nm.

Subsequently, as shown in FIG. 7, of the second top layer 632a, the portion exposed from the resist R1 is removed by wet etching. Further, of the first top layer 631a, the portion exposed from the resist R1 is removed by anisotropic dry etching. By these etching processes, the top portion 63 including the first top layer 631 and the second top layer 632 is formed.

In the anisotropic dry etching described above, the thickness of, of the second layer L2, the portion exposed from the resist R1 and the top portion 63 is also reduced. It should be noted that the configuration is not limited to this example. Of the second layer L2, the portion exposed from the resist R1 may be entirely removed. Further, the processes of the first top layer 631a and the second layer L2 shown in FIG. 7 may be performed by different types of etching.

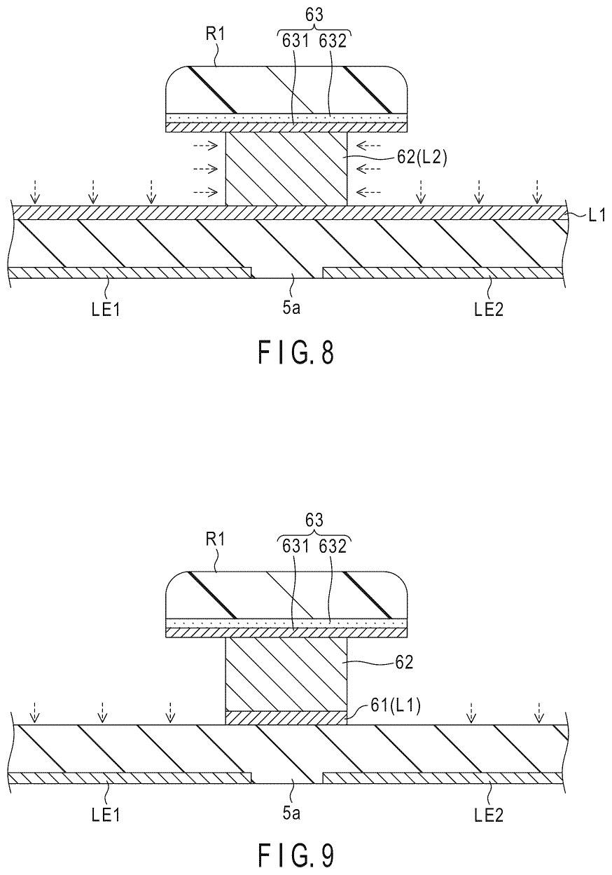

After the process of FIG. 7, as shown in FIG. 8, the second layer L2 is processed by isotropic wet etching. In this wet etching, of the second layer L2, the portion in which the thickness is reduced in the process of FIG. 7 is removed. Further, the width of the second layer L2 which remains under the top portion 63 is decreased so as to be less than the width of the top portion 63. In this manner, the stem portion 62 is formed.

After the process of FIG. 8, as shown in FIG. 9, of the first layer L1, the portion exposed from the stem portion 62 is removed by dry etching. By this process, the bottom portion 61 is formed. After the partition 6 is formed by the process of FIG. 6 to FIG. 9 described above, the resist R1 is removed.

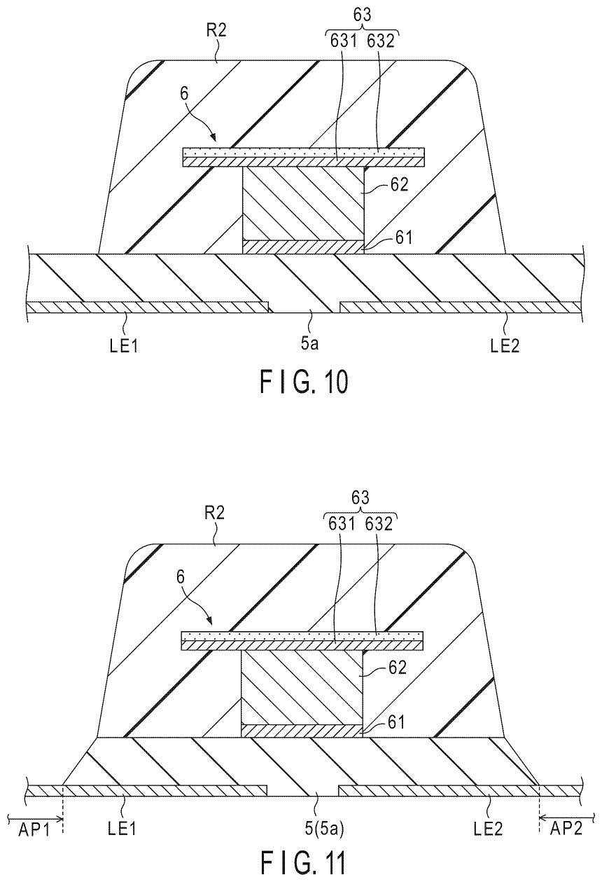

Subsequently, as shown in FIG. 10, a resist R2 patterned into the planar shape of the rib 5 is provided. Further, as shown in FIG. 11, of the insulating layer 5a, the portion exposed from the resist R2 is removed by dry etching. By this process, the rib 5 comprising the pixel apertures AP1, AP2 and AP3 is formed. After this dry etching, the resist R2 is removed.

In the example of FIG. 6 to FIG. 11, the pixel apertures AP1, AP2 and AP3 of the rib 5 are formed after the formation of the partition 6. As another example, the partition 6 may be formed after the formation of the pixel apertures AP1, AP2 and AP3. Moreover, the methods for processing the first layer L1, the second layer L2, the third layer L3 and the rib 5, such as the wet etching and dry etching described here as examples, could be appropriately modified depending on the materials of these portions.

After the formation of the rib 5 and the partition 6, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

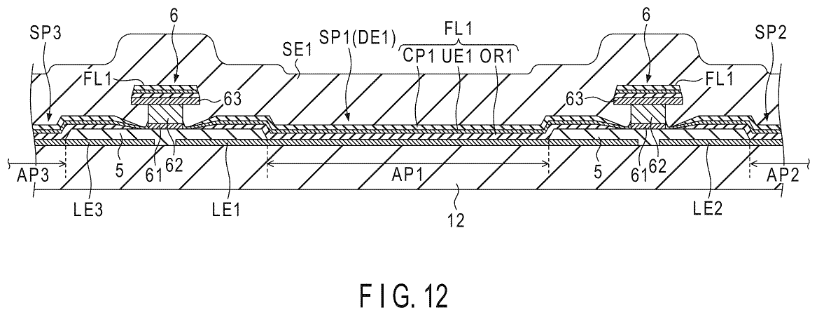

FIG. 12 to FIG. 17 are schematic cross-sectional views showing an example of a process for forming the display elements DE1, DE2 and DE3. To form the display element DE1, first, as shown in FIG. 12, the organic layer OR1 which covers the lower electrode LE1 through the pixel aperture AP1, the upper electrode UE1 which covers the organic layer OR1 and is in contact with the bottom portion 61 and the cap layer CP1 which covers the upper electrode UE1 are formed in order by vapor deposition, and further, the sealing layer SE1 which continuously covers the cap layer CP1 and the partition 6 is formed by chemical vapor deposition (CVD) (process PR3).

The thin film FL1 including the organic layer OR1, the upper electrode UE1 and the cap layer CP1 is formed in at least the entire display area DA, is provided in subpixels SP2 and SP3 as well as subpixel SP1 and is also provided on the partition 6. The thin film FL1 is divided by the partition 6 having an overhang shape. The sealing layer SE1 is formed in the entire display area DA and continuously covers the thin film FL1 and the partition 6 without being divided by the partition 6.

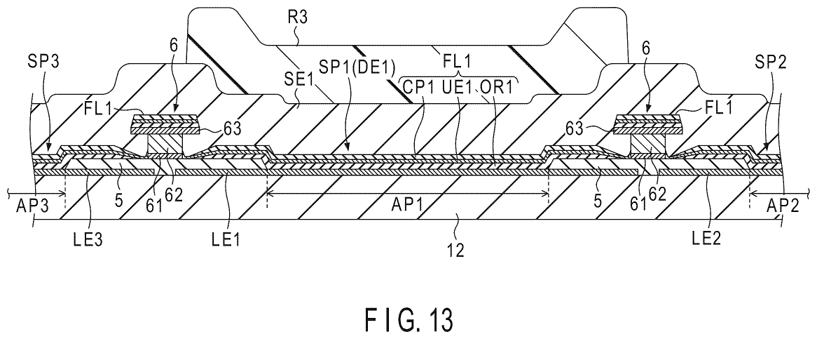

After process PR3, the thin film FL1 and the sealing layer SE1 are patterned (process PR4). In this patterning, as shown in FIG. 13, a resist R3 is provided on the sealing layer SE1. The resist R3 is located above subpixel SP1 and part of the partition 6 around subpixel SP1.

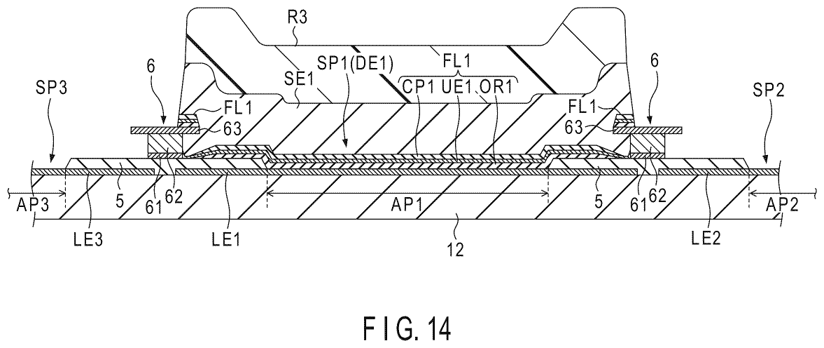

Subsequently, as shown in FIG. 14, of the thin film FL1 and the sealing layer SE1, the portions exposed from the resist R3 are removed by etching using the resist R3 as a mask. For example, this etching includes wet etching and dry etching processes which are performed in order for the sealing layer SE1, the cap layer CP1, the upper electrode UE1 and the organic layer OR1.

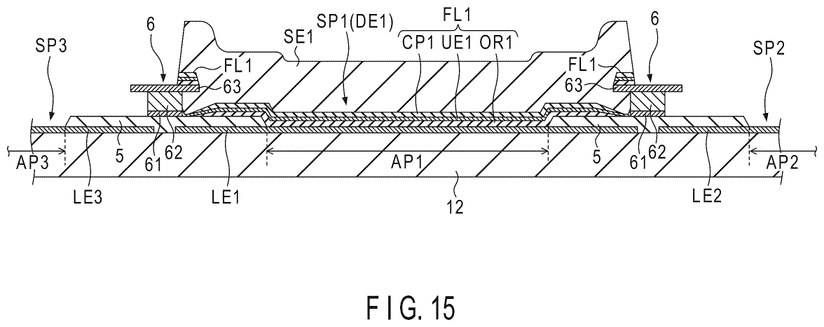

After the process shown in FIG. 14, the resist R3 is removed. This process allows the acquisition of the following substrate. As shown in FIG. 15, in the substrate, the display element DE1 and the sealing layer SE1 are formed in subpixel SP1, and neither a display element nor a sealing layer is formed in subpixel SP2 or subpixel SP3.

The display element DE2 is formed by a procedure similar to that of the display element DE1. Specifically, after process PR4, the organic layer OR2 which covers the lower electrode LE2 through the pixel aperture AP2, the upper electrode UE2 which covers the organic layer OR2 and the cap layer CP2 which covers the upper electrode UE2 are formed in order by vapor deposition, and further, the sealing layer SE2 which continuously covers the cap layer CP2 and the partition 6 is formed by CVD (process PR5).

The thin film FL2 including the organic layer OR2, the upper electrode UE2 and the cap layer CP2 is formed in at least the entire display area DA, is provided in subpixels SP1 and SP3 as well as subpixel SP2 and is also provided on the partition 6. The thin film FL2 is divided by the partition 6 having an overhang shape. The sealing layer SE2 is formed in the entire display area DA and continuously covers the thin film FL2 and the partition 6 without being divided by the partition 6.

After process PR5, the thin film FL2 and the sealing layer SE2 are patterned by wet etching and dry etching (process PR6). The flow of this patterning is similar to that of process PR4.

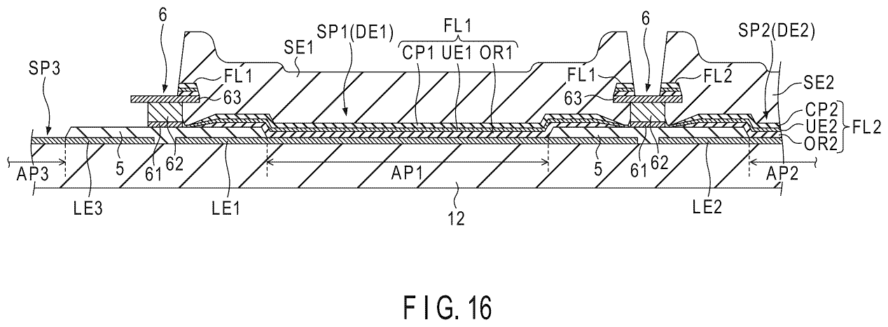

Process PR6 allows the acquisition of the following substrate. As shown in FIG. 16, in the substrate, the display element DE1 and the sealing layer SE1 are formed in subpixel SP1, and the display element DE2 and the sealing layer SE2 are formed in subpixel SP2, and neither a display element nor a sealing layer is formed in subpixel SP3.

The display element DE3 is formed by a procedure similar to the procedures of the display elements DE1 and DE2. Specifically, after process PR6, the organic layer OR3 which covers the lower electrode LE3 through the pixel aperture AP3, the upper electrode UE3 which covers the organic layer OR3 and the cap layer CP3 which covers the upper electrode UE3 are formed in order by vapor deposition, and further, the sealing layer SE3 which continuously covers the cap layer CP3 and the partition 6 is formed by CVD (process PR7).

The thin film FL3 including the organic layer OR3, the upper electrode UE3 and the cap layer CP3 is formed in at least the entire display area DA, is provided in subpixels SP1 and SP2 as well as subpixel SP3 and is also provided on the partition 6. The thin film FL3 is divided by the partition 6 having an overhang shape. The sealing layer SE3 is formed in the entire display area DA and continuously covers the thin film FL3 and the partition 6 without being divided by the partition 6.

After process PR7, the thin film FL3 and the sealing layer SE3 are patterned by wet etching and dry etching (process PR8). The flow of this patterning is similar to that of process PR4.

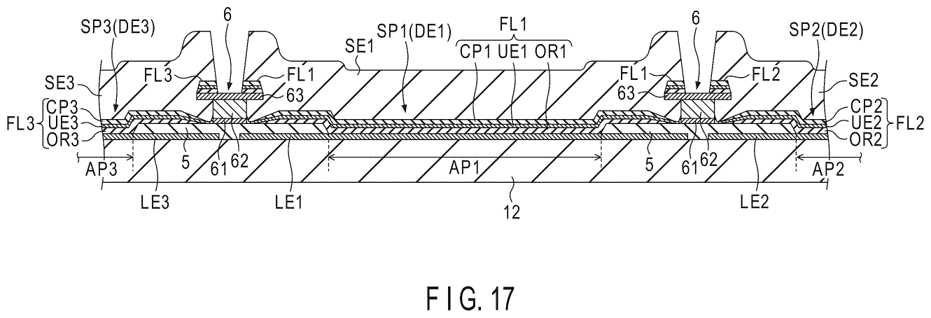

Process PR8 allows the acquisition of the following substrate. As shown in FIG. 17, in the substrate, the display element DE1 and the sealing layer SE1 are formed in subpixel SP1, and the display element DE2 and the sealing layer SE2 are formed in subpixel SP2, and the display element DE3 and the sealing layer SE3 are formed in subpixel SP3.

After the display elements DE1, DE2 and DE3 and the sealing layers SE1, SE2 and SE3 are formed, the resin layer 13, sealing layer 14 and resin layer 15 shown in FIG. 3 are formed in order (process PR9). By this process, the display device DSP is completed.

In the manufacturing method of the display device DSP of the embodiment explained above, the thin films FL1, FL2 and FL3 formed by vapor deposition are divided by the partition 6 having an overhang shape. Further, by covering these divided thin films FL1, FL2 and FL3 with the sealing layers SE1, SE2 and SE3, respectively, the display elements DE1, DE2 and DE3 which are individually sealed can be obtained. The partition 6 also functions as lines which supply electricity to the upper electrodes UE1, UE2 and UE3.

If the sealing layers SE1, SE2 and SE3 are thick, the optical loss of the light emitted by the display elements DE1, DE2 and DE3 could be increased. Therefore, as described above, thicknesses T2 of the sealing layers SE1, SE2 and SE3 should be desirably less than or equal to 1.5 μm and should be more desirably less than or equal to 1.0 μm.

To the contrary, if the sealing layers SE1, SE2 and SE3 are thin, there is a possibility that a void which is not filled with the sealing layer SE1, SE2 or SE3 is generated in the space under the top portion 63 which protrudes from the stem portion 62 (in other words, the space under the end portion E1 or E2 in FIG. 4).

For example, the resist R3 shown in FIG. 13 is a positive type of resist and is exposed and developed after being formed in the entire display area DA. If the resist R3 partly gets into the above void which is adjacent to subpixel SP2 or SP3 before exposure and development, this portion could remain as a residue after the development as it is not sufficiently exposed. If such a residue is present, there is a possibility that, of the sealing layer SE1, the portion which is covered with the residue is not removed in the process of the etching of FIG. 14. Thus, part of the sealing layer SE1 and the thin film FL1 located under such a portion may remain in subpixel SP2 or SP3. In this case, the conduction between the upper electrodes UE2 and UE3 which are formed later and the bottom portion 61 could be interrupted by the sealing layer SE1 and thin film FL1 which are undesirably left. In the process of forming the display element DE2, similarly, the residue of the resist for patterning the sealing layer SE2 and the thin film FL2 could be generated. Thus, the conduction between the upper electrode UE3 which is formed later and the bottom portion 61 could become defective.

The void described above can be prevented by lowering the partition 6. When the partition 6 is lowered, the space under the top portion 63 which protrudes from the stem portion 62 is small. Thus, even if the sealing layers SE1, SE2 and SE3 are thin, the void described above is not easily generated. From this point of view, height H shown in FIG. 4 should be desirably less than or equal to 500 nm.

When height H is decreased to 500 nm or less, the interval between the top portion 63 and the first layer L1 is decreased in the partition 6 shown in FIG. 8 in the middle of formation. Thus, there is a possibility that the first layer L1 cannot be sufficiently removed in the dry etching shown in FIG. 9 depending on the material of the first layer L1. In this manner, the both end portions of the bottom portion 61 may protrude from the stem portion 62. In this case, the organic layers OR1, OR2 and OR3 which are formed later may be in contact with the bottom portion 61, and thus, undesired leak current may flow between the organic layers OR1, OR2 and OR3 and the bottom portion 61. For example, when the material of the bottom portion 61 (first layer L1) is titanium nitride (TiN), as the etching rate in dry etching is relatively slow, this problem easily occurs.

To the contrary, the molybdenum-tungsten alloy which is the material of the bottom portion 61 (first layer L1) of the embodiment has excellent processability for the dry etching shown in FIG. 9. Therefore, even if height H of the partition 6 is decreased to 500 nm or less, of the first layer L1, the portion exposed from the stem portion 62 can be satisfactorily removed.

If the bottom portion 61 does not protrude from the stem portion 62, the contact area of the bottom portion 61 and the upper electrode UE1, UE2 or UE3 becomes less. However, when thickness T1 of the bottom portion 61 is greater than or equal to 50 nm as described above, the contact area of the upper electrode UE1, UE2 or UE3 and the bottom portion 61 can be made great. In this manner, the conduction between the upper electrode UE1, UE2 or UE3 and the bottom portion 61 becomes satisfactory.

As described above, according to the display device DSP and the manufacturing method thereof in the embodiment, the partition 6 having an overhang shape can be accurately formed, and further, the defective conduction between the upper electrodes UE1, UE2 and UE3 and the partition 6 can be prevented. Thus, the yield of the display device DSP can be improved.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib comprising a pixel aperture which overlaps the lower electrode;
a partition which includes a conductive bottom portion provided on the rib, a stem portion provided on the bottom portion, and a top portion provided on the stem portion and protruding from a side surface of the stem portion;
an organic layer which covers the lower electrode through the pixel aperture and emits light based on application of voltage;
an upper electrode which covers the organic layer and is in contact with the bottom portion; and
a sealing layer which continuously covers the partition and a thin film including the organic layer and the upper electrode, wherein
the bottom portion is formed of a molybdenum-tungsten alloy,
a height from a lower surface of the bottom portion to an upper surface of the stem portion is less than or equal to 500 nm,
a thickness of the sealing layer is less than or equal to 1.5 μm, and
a thickness of the bottom portion is greater than or equal to 50 nm.

2. The display device of claim 1, wherein
the stem portion is formed of aluminum.

3. The display device of claim 1, wherein
a width of the bottom portion is equal to a width of the stem portion.

4. The display device of claim 1, wherein
the rib is formed of silicon oxynitride.

5. The display device of claim 1, wherein
the sealing layer is formed of silicon nitride.

6. The display device of claim 1, wherein
the thickness of the bottom portion is less than or equal to 100 nm.

7. The display device of claim 1, wherein
the top portion comprises a first top layer, and a second top layer provided on the first top layer.

8. The display device of claim 7, wherein
the first top layer is formed of titanium, and
the second top layer is formed of ITO.

9. The display device of claim 1, wherein
the thin film further includes an optical adjustment layer which covers the upper electrode, and
the optical adjustment layer is formed of a material which is different from the upper electrode and the sealing layer.

10. The display device of claim 1, wherein
the upper electrode is in contact with a side surface of the bottom portion and the side surface of the stem portion.

11. A manufacturing method of a display device, including:
forming a lower electrode;
forming a rib which covers at least part of the lower electrode;
forming a partition on the rib, the partition including a conductive bottom portion, a stem portion located on the bottom portion and a top portion located on the stem portion;
forming an organic layer which covers the lower electrode and emits light based on application of voltage;
forming an upper electrode which covers the organic layer and is in contact with the bottom portion; and
forming a sealing layer which continuously covers the partition and a thin film including the organic layer and the upper electrode and has a thickness less than or equal to 1.5 μm, wherein
the forming the partition includes:
forming a first layer having a thickness greater than or equal to 50 nm using a molybdenum-tungsten alloy;
forming a second layer on the first layer, the second layer comprising an upper surface in which a height from a lower surface of the first layer is less than or equal to 500 nm;
forming a third layer on the second layer;
forming a resist on the third layer;
forming the top portion by removing a portion of the third layer exposed from the resist;
forming the stem portion by removing a portion of the second layer exposed from the top portion and by decreasing a width of the second layer which remains under the top portion so as to be less than a width of the top portion; and
forming the bottom portion by removing a portion of the first layer exposed from the stem portion.

12. The manufacturing method of claim 11, wherein
the first layer is formed by sputtering on a film formation condition which is less than or equal to 100° C.

13. The manufacturing method of claim 11, wherein
the second layer is formed of aluminum.

14. The manufacturing method of claim 11, wherein
the rib is formed of silicon oxynitride.

15. The manufacturing method of claim 11, wherein
the sealing layer is formed of silicon nitride.

16. The manufacturing method of claim 11, wherein
the first layer has a thickness which is less than or equal to 100 nm.

17. The manufacturing method of claim 11, wherein
the third layer comprises a first top layer, and a second top layer provide on the first top layer.

18. The manufacturing method of claim 17, wherein
the first top layer is formed of titanium, and
the second top layer is formed of ITO.

19. The manufacturing method of claim 11, wherein
the thin film further includes an optical adjustment layer which covers the upper electrode, and
the optical adjustment layer is formed of a material which is different from the upper electrode and the sealing layer.

20. The manufacturing method of claim 11, wherein
the upper electrode is formed so as to be in contact with a side surface of the bottom portion and a side surface of the stem portion.
